(19) United States
(12) Patent Application Publication
(10) Pub. No.: US 2013/0314910 A1
(43) Pub. Date: Nov. 28, 2013

(54) Circuit Board, LED Light Strip and Method for Making the LED Light Strip

(71) Applicants: Chong Huang, Shenzhen (CN); Yu-chun Hsiao, Shenzhen (CN); Yi-cheng Kuo, Shenzhen (CN)

(72) Inventors: Chong Huang, Shenzhen (CN); Yu-chun Hsiao, Shenzhen (CN); Yi-cheng Kuo, Shenzhen (CN)

(73) Assignee: SHENZHEN CHINA STAR OPTOELECTRONICS TECHNOLOGY CO. LTD, Shenzhen (CN)

(21) Appl. No.: 13/519,352

(22) PCT Filed: May 31, 2012
(86) PCT No.: PCT/CN12/76315

§ 371 Date: Jun. 27, 2012

(30) Foreign Application Priority Data
May 22, 2012 (CN) 201210160447.6

(51) Int. Cl. F21V 29/00; H01L 33/48

(52) U.S. Cl. 362/218; 438/26; 257/E33.056

(57) ABSTRACT

The present invention discloses a printed circuit board, a LED light strip and a method for making the LED light strip. A LED light source is disposed on the printed circuit board, and at least a portion thereof is covered with a layer of white heat dissipating paint. By way of this arrangement, the printed circuit board is partially deployed with a layer of heat dissipating material so as to increase the heat dissipation thereof. As a result, the heat built-up from LED light source on the printed circuit board can be effectively dissipated.

### FIELD OF THE INVENTION

The present invention relates to a technology of optoelectronic, and more particularly to a circuit board, LED light, and a method for making the LED light.

### DESCRIPTION OF PRIOR ART

LED is featured and known for its prolonged service life, low energy exhaustion, quick response, and a slim and compact dimension. As a result, the LED has been widely applied in the field of illumination. Specially, the LED has been used as the light source of a backlight module for a liquid crystal display module. Currently, a plurality of LEDs are disposed on a printed circuit board so as to form a LED strip, and then this LED strip is attached to a aluminum excursion or back frame made from aluminum. Even the LED features with low energy consumption, while when it is lit up, the LED can still generate a great deal of heat, and that heat build-up has to be dissipated by the aluminum excursion or back frame. However, the printed circuit board does not have good heat conduction, as a result, it can not create a satisfactory heat dissipation result.

### SUMMARY OF THE INVENTION

The present invention is to provide a circuit board, LED light strip, and a method for making the LED light strip so as to resolve the prior art issue, and enhance the heat dissipation of the heat built-up on the LED strip mounted on the circuit board.

In order to resolve the prior art issue, the present invention provides with a technical solution by providing an LED light strip, characterized in that the LED light strip includes a printed circuit, and a LED light source disposed on the printed circuit board. The printed circuit board is a metal core printed circuit board, and at least a portion thereof is covered with a layer of white heat dissipating paint.

Wherein the layer of white heat dissipation paint is deployed on a surface in which the LED light source is mounted.

Wherein the surface area of the printed circuit board is completely deployed with white heat dissipating paint.

Wherein at least a portion of the LED light source is covered with the white heat dissipating paint.

Wherein the LED light source includes a bracket, a LED chip disposed on the bracket, and lead frame disposed on the bracket and interconnected with the LED chip, wherein the white heat dissipating paint is deployed onto the surfaces of the bracket and the lead frame.

In order to resolve the prior art issue, the present invention provides with a technical solution by providing a printed circuit board used for fixing a LED light source thereon, characterized in that at least a portion of the printed circuit board is deployed with a layer of heat dissipation material.

that the printed circuit board is a metal core printed circuit board.

Wherein the layer of white heat dissipation paint is deployed on a surface in which the LED light source is mounted.

Wherein the surface area of the printed circuit board is completely deployed with white heat dissipating paint.

In order to resolve the prior art issue, the present invention provides with a technical solution by providing a method for making a LED light strip, characterized in that the method includes the steps of 1) deploying a layer of heat dissipating material over at least a portion of a printed circuit board; and 2) mounting the LED source onto the printed circuit board.

The invention can be concluded with the following advantages. As compared with the existing prior art, the printed circuit board made in accordance with the present invention is deployed with a layer of heat dissipating material at least on a surface area thereof so as to enhance the heat dissipating performance. As a result, the heat generated by the LED light strip mounted on the printed circuit board can be effectively dissipated.

### BRIEF DESCRIPTION OF DRAWINGS

FIG. 1 is a top view of a printed circuit board made in accordance with a first embodiment of the present invention;

FIG. 2 is a top view of a printed circuit board made in accordance with a second embodiment of the present invention;

FIG. 3 is a side elevational view of a LED light strip made in accordance with a third embodiment of the present invention;

FIG. 4 is a side elevational view of a LED light strip made in accordance with a fourth embodiment of the present invention;

FIG. 5 is a side elevational view of a LED light strip made in accordance with a fifth embodiment of the present invention;

FIG. 6 is a flow diagram illustrating steps of a method of making a LED light strip made in accordance with a sixth embodiment of the present invention; and

FIG. 7 is a flow diagram illustrating steps of a method of making a LED light strip made in accordance with a seventh embodiment of the present invention.

### DETAILED DESCRIPTION OF PREFERRED EMBODIMENT

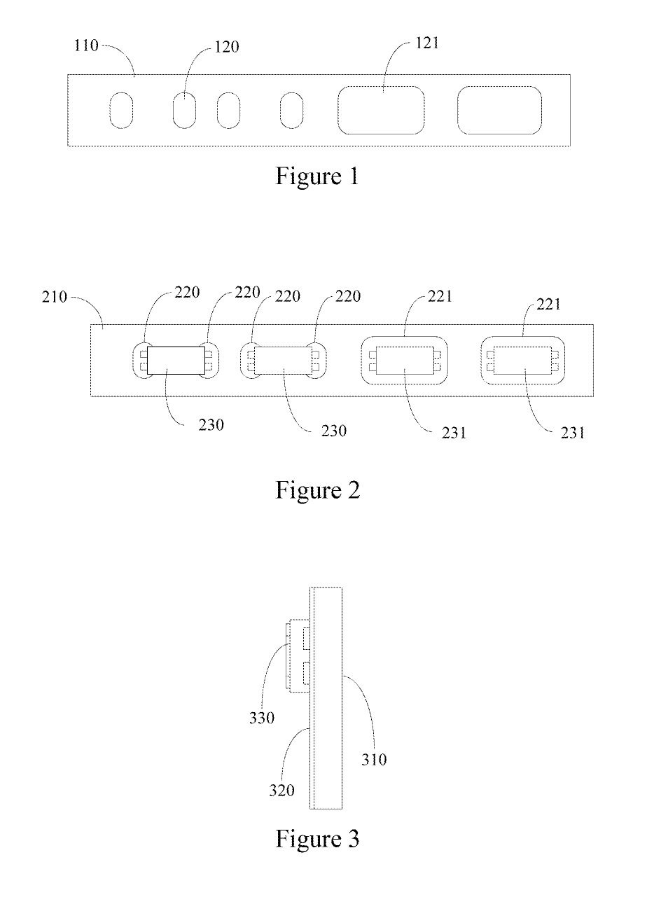

Referring to FIG. 1, a top view of a printed circuit board made in accordance with a first embodiment of the present invention. In this embodiment, the surface area of the printed circuit board 110 is partially coated with a layer of heat dissipating material 120, 121. The printed circuit board 110 is used to mount a LED light source (not show). The heat dissipating material 120, 121 is used to enhance the heat dissipation result of the printed circuit board 110. Consequently, the heat dissipating performance of the LED light source mounted on the printed circuit board 110 is also upgraded. In this current embodiment, the heat dissipating material 120 and 121 is merely coated to the surface area of the printed circuit board 110 in which the LED light source is mounted. However, in other alternative, the printed circuit board 110 can be coated partially or completely with the heat dissipating material 120.

Referring to FIG. 2, a top view of a printed circuit board made in accordance with a second embodiment of the present invention. In this current embodiment, the printed circuit board 210 is partially coated with a heat dissipating material 220 and 221. In this embodiment, the heat dissipating material 220, 221 is deployed with the same manner as the heat dissipating material 120, 121 disclosed in the first embodiment.

The LED light source 230 and 231 are mounted on the printed circuit board 210. Wherein portion of the LED light source 230 is mounted onto the heat dissipating material 220, while the LED light source 231 is completely mounted onto heat dissipating material 221. Both of the mounting can enhance the heat dissipating performance of the LED 230 and 231 mounted on the printed circuit board 210. Of course, in other embodiment, the LED light source can be mounted on other surface area which is not covered by the heat dissipating material 220, 221. In order to ensure the emitted light will not be affected by the LED light source 230, 231, the heat dissipating material 220, 221 is preferably embodied in white paint.

In those above described embodiment, the printed circuit board 110, and 210 are preferred embodied as metal core printed circuit board (MCPCB). The metal core printed circuit board has a certain heat conductive capability. As a result, not matter where the heat dissipating paint is deployed, it can enhance its heat conductivity, and consequently its heat dissipating capability. As a result, the heat dissipating performance of the LED mounted thereupon is also enhanced.

Referring now to FIG. 3, which a side elevational view of a LED light strip made in accordance with a third embodiment of the present invention. In this embodiment, the heat dissipating material 320 is coated over a surface area of a printed circuit board 310 in which a LED light source 330 is mounted in advance. In this embodiment, the printed circuit board 310 is completely coated with the heat dissipating material 320. This arrangement will simplify the overall coating process. In addition, the LED light source 330 can be mounted upon the heat dissipating material 320.

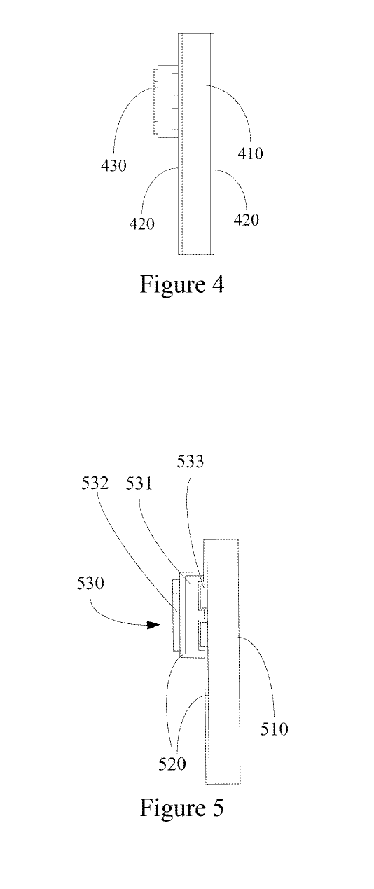

Referring to FIG. 4, a side elevational view of a LED light strip made in accordance with a fourth embodiment of the present invention. In this embodiment, a heat dissipating material 420 is coated over a surface area of a printed circuit board 410 in which a LED light source 430 is mounted. In addition, the heat dissipating material is also coated to opposite surface of the printed circuit board 410.

Referring to FIG. 5 which is a side elevational view of a LED light strip made in accordance with a fifth embodiment of the present invention. In this embodiment, an LED light source 530 is mounted onto a printed circuit board 510 in advance, and then a layer of heat dissipating material 520 is then coated over the printed circuit board 510 such that the LED light source 530 is partially coated with the heat dissipating material 520. Substantially, the LED light source 530 generally includes a bracket 531, a LED chip 532, and a lead frame 533 arranged on the bracket 531 so as to power the LED chip 532. The heat dissipating material 520 is preferably coated over the surface of the bracket 531 and the lead frame 532 in a prioritized manner.

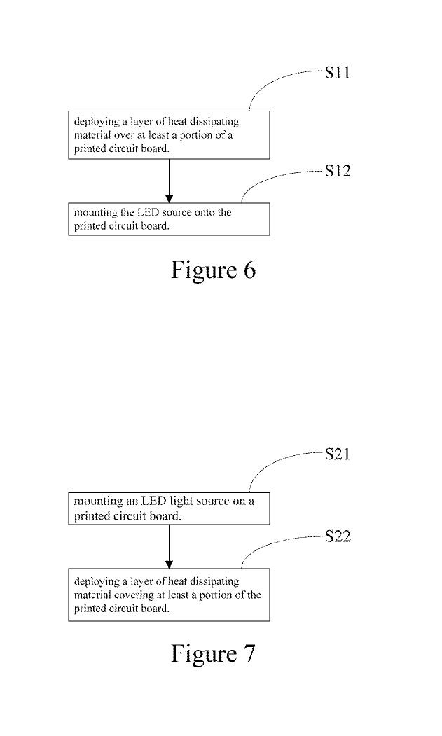

Referring to FIG. 6, which is a flow diagram illustrating steps of a method of making a LED light strip made in accordance with a sixth embodiment of the present invention. In this current embodiment, the method for making the LED light strip includes the steps of:

In step S11: 1) deploying a layer of heat dissipating material over at least a portion of a printed circuit board.

In Step S12: mounting the LED source onto the printed circuit board.

Referring to FIG. 7, which is a flow diagram illustrating steps of a method of making a LED light strip made in accordance with a seventh embodiment of the present invention. In this current embodiment, the method for making the LED light strip includes the steps of:

In Step S21: mounting an LED light source on a printed circuit board.

In step S22: deploying a layer of heat dissipating material covering at least a portion of the printed circuit board.

In the seventh embodiment of the present invention, at least a portion of the LED light source can be coated with the LED light source. In addition, the printed circuit board, the LED light source and the heat dissipating material can be referred to the first to fifth embodiments. Accordingly, no detailed description is given.

As compared with the existing prior art, the printed circuit board made in accordance with the present invention is deployed partially with a layer of heat dissipating material at least on a surface area thereof so as to enhance the heat dissipating performance. As a result, the heat generated by the LED light strip mounted on the printed circuit board can be effectively dissipated.

Embodiments of the present invention have been described, but not intending to impose any unduly constraint to the appended claims. Any modification of equivalent structure or equivalent process made according to the disclosure and drawings of the present invention, or any application thereof, directly or indirectly, to other related fields of technique, is considered encompassed in the scope of protection defined by the claims of the present invention.

1. An LED light strip, characterized in that the LED light strip includes a printed circuit, and a LED light source disposed on the printed circuit board, the printed circuit board is a metal core printed circuit board, and at least a portion thereof is covered with a layer of white heat dissipating paint.

2. The LED light strip as recited in claim 1, characterized in that the layer of white heat dissipation paint is deployed on a surface in which the LED light source is mounted.

3. The LED light strip as recited in claim 1, characterized in that the surface area of the printed circuit board is completely deployed with white heat dissipating paint.

4. The LED light strip as recited in claim 1, characterized in that at least a portion of the LED light source is covered with the white heat dissipating paint.

5. The LED light strip as recited in claim 4, characterized in that the LED light source includes a bracket, a LED chip disposed on the bracket, and lead frame disposed on the bracket and interconnected with the LED chip, wherein the white heat dissipating paint is deployed onto the surfaces of the bracket and the lead frame.

6. A printed circuit board used for fixing a LED light source thereon, characterized in that at least a portion of the printed circuit board is deployed with a layer of heat dissipation material.

7. The LED light strip as recited in claim 6, characterized in that the printed circuit board is a metal core printed circuit board.

8. The LED light strip as recited in claim 6, characterized in that the layer of white heat dissipation paint is deployed on a surface in which the LED light source is mounted.

9. The LED light strip as recited in claim 6, characterized in that the surface area of the printed circuit board is completely deployed with white heat dissipating paint.

10. A method for making a LED light strip, characterized in that the method includes the steps of:
1) deploying a layer of heat dissipating material over at least a portion of a printed circuit board; and
2) mounting the LED source onto the printed circuit board.
